(19) United States
(12) Patent Application Publication
(10) Pub. No.: US 2026/0100366 A1
(43) Pub. Date: Apr. 9, 2026

(54) SILICON-CARBON ANODE MATERIAL BASED ON ORGANOSILICON-DERIVED WASTE SILICON POWDER, AND PREPARATION METHOD THEREFOR AND USE THEREOF

(71) Applicants: KUNMING UNIVERSITY OF SCIENCE AND TECHNOLOGY, Kunming (CN); YUNNAN UNIVERSITY, Kunming (CN)

(72) Inventors: Fengshuo XI, Kunming (CN); Zichuan CHENG, Kunming (CN); Wenhui MA, Kunming (CN); Shaoyuan LI, Kunming (CN); Kuixian WEI, Kunming (CN); Xiuhua CHEN, Kunming (CN); Jijun LU, Kunming (CN)

(73) Assignees: KUNMING UNIVERSITY OF SCIENCE AND TECHNOLOGY, Kunming (CN); YUNNAN UNIVERSITY, Kunming (CN)

(21) Appl. No.: 19/415,865

(22) Filed: Dec. 11, 2025

Related U.S. Application Data
(63) Continuation of application No. PCT/CN2025/092821, filed on May 6, 2025.

(30) Foreign Application Priority Data
May 25, 2024 (CN) 202410657132.5

(51) Int. Cl. H01M 4/587; C23C 16/26; C23C 16/44; H01M 10/0525

(52) U.S. Cl. CPC H01M 4/587; C23C 16/26; C23C 16/4417; H01M 10/0525

(57) ABSTRACT

The preparation method for a silicon-carbon anode material based on organosilicon-derived waste silicon powder includes: performing rapid annealing treatment on organosilicon-derived waste silicon powder, and mixing the rapidly annealed waste silicon powder with an acid solution for acid leaching to obtain modified waste silicon powder; performing mechanical grinding on the modified waste silicon powder to obtain a modified waste silicon powder abrasive; mixing the modified waste silicon powder abrasive with an organic carbon source and a solvent to obtain a precursor solution, and performing spray granulation on the precursor solution to obtain silicon-carbon microspheres; and introducing a carbon-deposition precursor source, and performing carbon deposition on the silicon-carbon microspheres to obtain a silicon-carbon anode material.

### CROSS REFERENCE TO THE RELATED APPLICATIONS

This application is a continuation application of International Application of International Application No. PCT/CN2025/092821, filed on May 6, 2025, which is based upon and claims priority to Chinese Patent Application No. 202410657132.5, filed on May 25, 2024, the entire contents of which are incorporated herein by reference.

### TECHNICAL FIELD

The present invention relates to the technical field of lithium-ion batteries, and in particular, to a silicon-carbon anode material based on organosilicon-derived waste silicon powder, and a preparation method therefor and use thereof.

### BACKGROUND

An organosilicon material is a special polymer that simultaneously possesses an organic structural unit and an inorganic structural unit. The organosilicon material has extremely complex production and preparation process due to the special structure. A basic production process generally includes the following steps: (1) reacting silicon powder with chloromethane to synthesize an organosilicon monomer, where the silicon powder is metallic silicon meeting national production standards; (2) producing an organosilicon intermediate by subjecting the chlorosilane monomer in the organosilicon monomer to thermal decomposition or hydrolysis with water; and (3) further processing the unreacted organosilicon monomer from the previous step and the organosilicon intermediate obtained in the previous step through various reaction processes to produce the desired product. Currently, the most efficient and economical method for producing organosilicon monomers is to react chloromethane with silicon powder in the presence of a copper-based catalyst, such as metallic copper, copper chloride, or copper oxide.

To ensure that the heat generated during the reaction is promptly removed, manufacturers generally use a fluidized bed as the reaction device. To improve the utilization of silicon powder for conversion to organosilicon monomers in the fluidized bed reactor, two-stage cyclone separators are typically installed at the rear end of the fluidized bed. With the centrifugal separation effect of the cyclone separators, unreacted copper-based catalyst, chloromethane, crude monomer, and fine silicon powder particles can be separated. However, during the cyclone separation process, a significant portion of fine silicon powder and copper-based catalyst still exits together with the gaseous crude monomer and chloromethane, forming organosilicon-derived waste silicon powder. The organosilicon-derived waste silicon powder has a fine particle size and a high copper content, and the failure to effectively recover and utilize the organosilicon-derived waste silicon powder results in a substantial waste of resources. The organosilicon-derived waste silicon powder has a small average particle size and contains organosilicon and fine copper powder, resulting in high reactivity. Exposure of the organosilicon-derived waste silicon powder to air easily causes oxidation or even combustion, creating significant safety hazards during storage. More importantly, due to the fine particle size, complex composition, and high impurity content of the organosilicon-derived waste silicon powder, research progress on effective recovery of the organosilicon-derived waste silicon powder has been relatively slow. The disposal of organosilicon-derived waste silicon powder generated during organosilicon production has become a major challenge facing the organosilicon industry.

### SUMMARY

An objective of the present invention is to provide a silicon-carbon anode material based on organosilicon-derived waste silicon powder, and a preparation method therefor and use thereof, which address the difficulty in disposing of organosilicon-derived waste silicon powder generated during organosilicon production.

To achieve the foregoing objective, the present invention provides the following technical solutions.

The present invention provides a method for preparing a silicon-carbon anode material based on organosilicon-derived waste silicon powder, which includes the following steps:
(1) performing rapid annealing treatment on organosilicon-derived waste silicon powder, and mixing the rapidly annealed waste silicon powder with an acid solution for acid leaching to obtain modified waste silicon powder;
(2) performing mechanical grinding on the modified waste silicon powder in step (1) to obtain a modified waste silicon powder abrasive, mixing the modified waste silicon powder abrasive with an organic carbon source and a solvent to obtain a precursor solution, and performing spray granulation on the obtained precursor solution to obtain silicon-carbon microspheres; and
(3) introducing a carbon-deposition precursor source, and performing carbon deposition on the silicon-carbon microspheres in step (2) to obtain the silicon-carbon anode material; where

in step (1), the organosilicon-derived waste silicon powder contains elemental silicon, copper components, and organosilicon residues; and
in step (1), a temperature for the rapid annealing treatment is 200-1500° C., a holding time for the rapid annealing treatment is 0.1 h-20 h, and the rapid annealing treatment is performed 1-5 times.

Preferably, according to the method for preparing the silicon-carbon anode material based on the organosilicon-derived waste silicon powder, in step (1), an atmosphere for the rapid annealing treatment is air, argon, or nitrogen, a gas flow rate during the rapid annealing treatment is 10-600 mL/min, and a heating rate to the temperature for the rapid annealing treatment is 20-500° C./min.

Preferably, according to the method for preparing the silicon-carbon anode material based on the organosilicon-derived waste silicon powder, in step (1), acid in the acid solution is one or more selected from hydrochloric acid, sulfuric acid, nitric acid, or hydrofluoric acid, a concentration of the acid in the acid solution is 0.01-5 mol/L, a liquid-to-solid ratio of the acid solution to the rapidly annealed waste silicon powder is ≥3 mL: 1 g, a temperature for the acid leaching is 0-80° C., and a duration of the acid leaching is 0.01-20 h.

Preferably, according to the method for preparing the silicon-carbon anode material based on the organosilicon-derived waste silicon powder, in step (1), the acid solution further includes an oxidizing agent, the oxidizing agent is H₂O₂, Fe(NO₃)₃, KMnO₄, KBrO₃, K₂Cr₂O₇, or Na₂S₂O₈, and a concentration of the oxidizing agent in the acid solution is 0-10 mol/L.

Preferably, the method for preparing the silicon-carbon anode material based on the organosilicon-derived waste silicon powder, in step (2), the modified waste silicon powder is mixed with a carbon material and then subjected to mechanical grinding, the carbon material is one or more of carbon fiber, mesophase carbon microspheres, graphite, hard carbon, porous activated carbon, carbon nanotubes, graphene, and pitch, and a mass of the carbon material is 0-100 wt % of a mass of the modified waste silicon powder.

Preferably, according to the method for preparing the silicon-carbon anode material based on the organosilicon-derived waste silicon powder, in step (2), the organic carbon source includes one or more of glucose, phenol-formaldehyde resin, polydopamine, or citric acid, a mass of the organic carbon source is 1-60 wt % of the mass of the modified waste silicon powder abrasive, a solid content of the precursor solution is 1-30 wt %, an atmosphere used for the spray granulation is air, argon, or nitrogen; a feed rate for the spray granulation is 1-120 mL/min, an inlet gas flow rate for the spray granulation is 0.01-200 mL/min, and a temperature for the spray granulation is 80-350° C.

Preferably, according to the method for preparing the silicon-carbon anode material based on the organosilicon-derived waste silicon powder, in step (2), the precursor solution further includes a pore-forming agent, the pore-forming agent includes one or more of NaCl, MgCl₂, LiCl, KCl, or CaCl₂), and a mass of the pore-forming agent is 0-6 wt % of the mass of the modified waste silicon powder abrasive.

Preferably, according to the method for preparing the silicon-carbon anode material based on the organosilicon-derived waste silicon powder, in step (3), the carbon-deposition precursor source is a mixture of an active gas, hydrogen, and argon, the active gas is methane, acetylene, or carbon monoxide; a volume fraction of the active gas in the carbon-deposition precursor source is 10-60%, a volume fraction of the hydrogen in the carbon-deposition precursor source is 10-50%, and a volume fraction of the argon in the carbon-deposition precursor source is 10-50%; and a gas flow rate of the carbon-deposition precursor source is 0.1-100 mL/min, a temperature for the carbon deposition is 400-1300° C., and a duration of the carbon deposition is 0.1-20 h.

The present invention further provides a silicon-carbon anode material prepared by the method for preparing the silicon-carbon anode material based on the organosilicon-derived waste silicon powder.

The present invention further provides use of the silicon-carbon anode material in lithium-ion batteries.

It may be known from the technical solutions that, compared with the prior art, the present invention has the following beneficial effects.

Based on the compositional characteristics of organosilicon-derived waste silicon powder, the waste silicon powder is first modified by combining rapid annealing treatment with selective acid leaching. The silicon material is then refined by mechanical grinding, and copper is uniformly distributed within the silicon. Subsequently, a spray granulation method is used to obtain micron-sized silicon-carbon microspheres with a particle size distribution of 5-30 μm. Finally, a dense carbon layer is deposited on the surface of the silicon-carbon microspheres through the catalytic effect of copper, yielding Si/C/Cu microspheres. The Si/C/Cu microspheres exhibit high density and sphericity, which enables efficient stacking to improve tap density, thereby increasing the loading of active material and the effective capacity of the microspheres as anode material. This approach facilitates the development of a novel high-tap-density silicon-carbon anode material, and provides a new approach and pathway for the value-added reutilization of difficult-to-treat organosilicon-derived waste silicon powder in the organosilicon industry and for the low-cost development of high-performance silicon-based anodes for lithium-ion batteries.

The present invention has the advantages of simple equipment requirements, ease of operation, and suitability for large-scale industrial production.

### BRIEF DESCRIPTION OF THE DRAWINGS

To more clearly illustrate the technical solutions in the examples of the present invention or in the prior art, the drawings used in the description of the examples or the prior art are briefly introduced below.

FIG. 1 is a morphological view of the silicon-carbon anode material obtained in Example 1;

FIG. 2 is a morphological view of the silicon-carbon anode material obtained in Example 2;

FIG. 3 is a morphological view of the silicon-carbon anode material obtained in Example 3;

FIG. 4 is a morphological view of the silicon-carbon anode material obtained in Example 4; and

FIG. 5 is a morphological view of the silicon-carbon anode material obtained in Example 5.

### DETAILED DESCRIPTION OF THE EMBODIMENTS

The present invention provides a method for preparing a silicon-carbon anode material based on organosilicon-derived waste silicon powder, which includes the following steps:
(1) performing rapid annealing treatment on organosilicon-derived waste silicon powder, and mixing the rapidly annealed waste silicon powder with an acid solution for acid leaching to obtain modified waste silicon powder;
(2) performing mechanical grinding on the modified waste silicon powder in step (1) to obtain a modified waste silicon powder abrasive, mixing the modified waste silicon powder abrasive with an organic carbon source and a solvent to obtain a precursor solution, and performing spray granulation on the obtained precursor solution to obtain silicon-carbon microspheres; and
(3) introducing a carbon-deposition precursor source, and performing carbon deposition on the silicon-carbon microspheres in step (2) to obtain the silicon-carbon anode material; where
in step (1), the organosilicon-derived waste silicon powder contains elemental silicon, copper components, and organosilicon residues; and
in step (1), a temperature for the rapid annealing treatment is 200-1500° C., a holding time for the rapid annealing treatment is 0.1 h-20 h, and the rapid annealing treatment is performed 1-5 times.

According to the present invention, in step (1), the organosilicon-derived waste silicon powder contains elemental silicon, copper components, and organosilicon residues. Preferably, a content of the elemental silicon is 60-95 wt %, further preferably 88-93 wt %, and more preferably 89.4-90.5 wt %. Preferably, a content of the residual organosilicon is 0.1-20 wt %, further preferably 0.6-1.5 wt %, and more preferably 0.8-1.1 wt %. The copper component in the organosilicon-derived waste silicon powder is present in the form of copper oxide and elemental copper. Preferably, a content of the copper component is 0.1-15 wt %, further preferably 6.2-10.5 wt %, and more preferably 8.4-9.8 wt %.

According to the present invention, in step (1), a source of the organosilicon-derived waste silicon powder is a mixture formed during a synthesis process of an organosilicon monomer, where silicon powder and a copper-based catalyst are discharged together with gaseous crude monomer and chloromethane.

According to the present invention, in step (1), an atmosphere for the rapid annealing treatment is preferably air, argon, or nitrogen, further preferably argon or nitrogen, and more preferably argon;
the gas flow rate during the rapid annealing treatment is preferably 10-600 mL/min, further preferably 100-600 mL/min, and more preferably 300-400 mL/min;
the heating rate to the temperature for the rapid annealing treatment is preferably 20-500° C./min, further preferably 300-500° C./min, and more preferably 300-400° C./min;
the temperature for the rapid annealing treatment is 200-1500° C., preferably 600-1500° C., and further preferably 600-1000° C.;
the holding time for the rapid annealing treatment is 0.1-20 h, preferably 0.1-1 h, and further preferably 0.1-0.5 h; and
the number of times for the rapid annealing treatment is 1-5, preferably 1-3, and further preferably 1.

According to the present invention, a function of the rapid annealing treatment is to rapidly carbonize the residual organosilicon and regulate a carbon component therein, and in a case where the rapid annealing temperature is higher than 400° C., amorphous carbon is partially converted into nano-carbon materials such as carbon nanotubes and graphene.

According to the present invention, after the rapid annealing treatment in step (1), the method preferably further includes naturally cooling to 15-25° C. (room temperature), where the atmosphere of the rapid annealing treatment is maintained during the cooling process.

According to the present invention, in step (1), the acid in the acid solution is preferably one or more of hydrochloric acid, sulfuric acid, nitric acid, or hydrofluoric acid, further preferably one or more of hydrochloric acid, nitric acid, or hydrofluoric acid, and more preferably hydrofluoric acid.

According to the present invention, in a case where the acid solution preferably contains two or more acids, a ratio between different acids is not limited and can be adjusted based on a requirement.

According to the present invention, in step (1), the concentration of the acid in the acid solution is preferably 0.01-5 mol/L, further preferably 1-3 mol/L, and more preferably 2 mol/L.

According to the present invention, in step (1), the liquid-to-solid ratio of the acid solution to the waste silicon powder after rapid annealing treatment is preferably ≥3 mL: 1 g, further preferably ≥5 mL: 1 g, and more preferably ≥8 mL: 1 g.

According to the present invention, in step (1), the temperature for the acid leaching is preferably 0-80° C., further preferably 20-80° C., and more preferably 60-80° C.;
the duration of the acid leaching is preferably 0.01-20 h, further preferably 1-5 h, and more preferably 2-5 h.

According to the present invention, in step (1), the acid solution preferably further includes an oxidizing agent.

According to the present invention, the oxidizing agent is preferably H₂O₂, Fe(NO₃)₃, KMnO₄, KBrO₃, K₂Cr₂O₇, or Na₂S₂O₈, further preferably H₂O₂, KMnO₄, K₂Cr₂O₇, or Na₂S₂O₈, and more preferably H₂O₂.

According to the present invention, the concentration of the oxidizing agent in the acid solution is preferably 0-10 mol/L, further preferably 4-10 mol/L, and more preferably 4 mol/L.

According to the present invention, a function of the acid leaching is to purify the organosilicon-derived waste silicon powder. A function of adding the oxidizing agent in the acid leaching is to enhance the purification process.

According to the present invention, after the acid leaching in step (1), the method preferably further includes sequentially performing filtration, washing, and drying.

According to the present invention, parameters for the sequential filtration, washing, and drying are not limited and may be performed according to procedures well known to those skilled in the art.

According to the present invention, in step (2), a method for the mechanical grinding is preferably ball milling or sand milling, further preferably sand milling.

According to the present invention, in step (2), the rotational speed for the mechanical grinding is preferably ≥1000 r/min, further preferably ≥1200 r/min, and more preferably ≥1500 r/min; and
the duration of the mechanical grinding is preferably ≥2 h, further preferably ≥5 h, and more preferably ≥10 h.

According to the present invention, in step (2), the modified waste silicon powder is mixed with a carbon material and then mechanically ground.

According to the present invention, the carbon material is preferably one or more of carbon fiber, mesophase carbon microspheres, graphite, hard carbon, porous activated carbon, carbon nanotubes, graphene, or asphalt, further preferably one or more of mesophase carbon microspheres, graphite, carbon nanotubes, or asphalt, and more preferably one or two of graphite or carbon nanotubes.

According to the present invention, in a case where there are two carbon materials, a ratio between two carbon materials is not limited and may be adjusted based on a requirement.

According to the present invention, the source of the carbon material is not limited and may be commercially available products well known to those skilled in the art.

According to the present invention, the mass of the carbon material is preferably 0-100 wt % of the mass of the modified waste silicon powder, further preferably 20-80 wt %, and more preferably 60-70 wt %.

According to the present invention, in step (2), the average particle size of the modified waste silicon powder abrasive is preferably 0.05-6 μm, further preferably 0.05-0.3 μm, and more preferably 0.05-0.1 μm.

According to the present invention, in step (2), the organic carbon source preferably includes one or more of glucose, phenolic resin, polydopamine, or citric acid, further preferably one or more of glucose, phenolic resin, or citric acid, and more preferably one or two of glucose or citric acid.

According to the present invention, in a case where there are two organic carbon sources, a ratio between two organic carbon sources is not limited and may be adjusted based on a requirement.

According to the present invention, the source of the organic carbon source is not limited and may be commercially available products well known to those skilled in the art.

In the present invention, in step (2), the mass of the organic carbon source is preferably 1-60 wt % of the mass of the modified waste silicon powder abrasive, further preferably 10-50 wt %, and more preferably 40-50 wt %.

According to the present invention, in step (2), the solvent is preferably water or alcohol, further preferably alcohol.

According to the present invention, the alcohol is preferably one or more of ethanol, methanol, or ethylene glycol, further preferably one or more of ethanol or ethylene glycol, and more preferably ethanol.

According to the present invention, in step (2), the precursor solution preferably further includes a pore-forming agent.

According to the present invention, the pore-forming agent preferably includes one or more of NaCl, MgCl₂, LiCl, KCl, or CaCl₂), further preferably one or more of NaCl, MgCl₂, or CaCl₂), and more preferably NaCl.

According to the present invention, in a case where there are two pore-forming agents, a ratio between two pore-forming agents is not limited and may be adjusted based on a requirement.

According to the present invention, the mass of the pore-forming agent is preferably 0-6 wt % of the mass of the modified waste silicon powder abrasive, further preferably 1-6 wt %, and more preferably 4-6 wt %.

According to the present invention, the function of adding the organic carbon source is to strengthen the bonding between silicon components and carbon components in the silicon-carbon microspheres and to provide a carbon source. The function of adding the pore-forming agent is to render the interior of the silicon-carbon microspheres porous in structure.

According to the present invention, in step (2), the solid content of the slurry for the spray granulation is preferably 1-30 wt %, further preferably 10-30 wt %, and more preferably 20-30 wt %.

According to the present invention, in step (2), the atmosphere used for the spray granulation is preferably air, argon, or nitrogen, further preferably argon or nitrogen, and more preferably argon.

According to the present invention, in step (2), the feeding rate for the spray granulation is preferably 1-120 mL/min, further preferably 1-10 mL/min, and more preferably 5-10 mL/min;
the inlet gas flow rate for the spray granulation is preferably 0.01-200 mL/min, further preferably 1-200 mL/min, and more preferably 100-200 mL/min; and

the temperature for the spray granulation is preferably 80-350° C., further preferably 80-150° C., and more preferably 110-150° C.

According to the present invention, in step (3), the carbon-deposition precursor source is preferably a mixture of active gas, hydrogen, and argon.

According to the present invention, the active gas is preferably one or more of methane, acetylene, or carbon monoxide, further preferably one or more of methane and acetylene, and more preferably acetylene.

According to the present invention, the volume fraction of the active gas in the carbon-deposition precursor source is preferably 10-60%, further preferably 30-60%, and more preferably 40-50%;
the volume fraction of the hydrogen in the carbon-deposition precursor source is preferably 10-50%, further preferably 30-50%, and more preferably 30-40%; and
the volume fraction of the argon in the carbon-deposition precursor source is preferably 10-50%, further preferably 10-40%, and more preferably 10-30%.

According to the present invention, the volume fractions of the raw materials in the carbon-deposition precursor source are preferably measured under standard conditions.

According to the present invention, in step (3), the gas flow rate of the carbon-deposition precursor source is preferably 0.1-100 mL/min, further preferably 0.1-80 mL/min, and more preferably 10-50 mL/min.

According to the present invention, in step (3), the temperature for the carbon deposition is preferably 400-1300° C., further preferably 600-1100° C., and more preferably 600-800° C.; and
the duration of the carbon deposition is preferably 0.1-20 h, further preferably 1-20 h, and more preferably 1-2 h.

The present invention further provides a silicon-carbon anode material prepared by the method for preparing the silicon-carbon anode material based on the organosilicon-derived waste silicon powder.

The present invention further provides use of the silicon-carbon anode material in lithium-ion batteries.

According to the present invention, the application method is not limited, and any method well known to those skilled in the art may be used.

The technical solutions in the examples of the present invention will be clearly and completely described below. Apparently, the described examples are merely a part, rather than all of the examples of the present invention. Based on the embodiments of the present invention, all other embodiments obtained by those of ordinary skill in the art without creative efforts shall fall within the protection scope of the present invention.

### Example 1

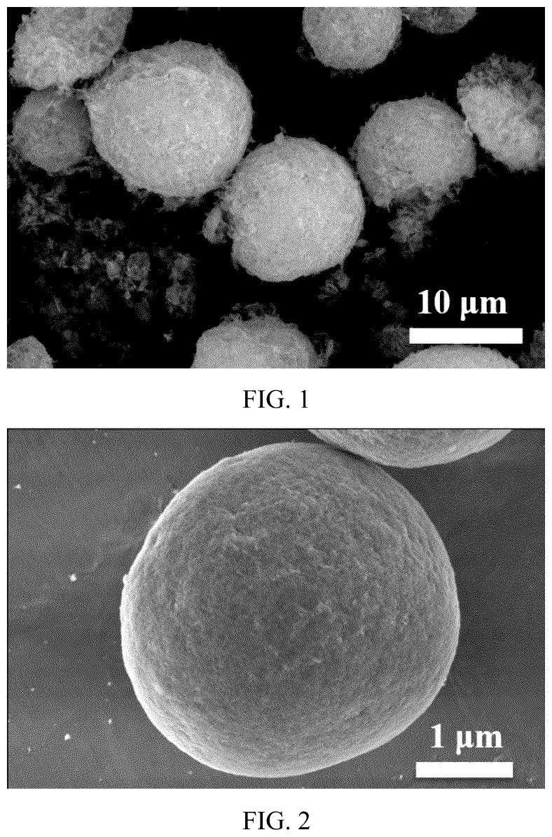

This example provides a method for preparing a silicon-carbon anode material based on organosilicon-derived waste silicon powder, which includes the following steps.
(1) The organosilicon-derived waste silicon powder, containing 89.8 wt % elemental silicon, 9.1 wt % copper, and 1.1 wt % organosilicon residue, was subjected to a single rapid annealing treatment under an argon atmosphere with an argon flow rate of 100 mL/min. The temperature was raised to 200° C. at a heating rate of 20° C./min and was maintained for 20 h. After annealing, the waste silicon powder was allowed to cool naturally to 20° C. together with the furnace, accompanied by argon during cooling. The rapidly annealed waste silicon powder was then subjected to acid leaching in a hydrofluoric acid-H₂O₂ mixed solution (the concentration of the hydrofluoric acid was 1 mol/L, the concentration of the H₂O₂ was 4 mol/L) with a liquid-to-solid ratio of 5 mL:1 g at 80° C. for 1 h under stirring. After acid leaching, the powder was filtered, washed, and dried to obtain modified waste silicon powder.
(2) The modified waste silicon powder obtained in step (1) was subjected to high-energy ball milling with graphite under the conditions of a rotation speed of 1000 r/min and a milling time of 5 h. The mass of graphite was 80 wt % of the mass of the modified waste silicon powder, resulting in a modified waste silicon powder abrasive having an average particle size of 0.1 μm. The modified waste silicon powder abrasive, glucose, NaCl, and ethanol were mixed, where the mass of the glucose was 20 wt % of the mass of the modified waste silicon powder abrasive and the mass of the NaCl was 1 wt % of the mass of the modified waste silicon powder abrasive, to obtain a precursor solution having a solid content of 10 wt %. Argon was introduced, and the precursor solution was spray-granulated at a feeding rate of 10 mL/min, an inlet gas flow rate of 1 mL/min, and a temperature of 110° C., whereby highly spherical silicon-carbon microspheres having an average particle size of 12 μm were self-assembled.
(3) A carbon-deposition precursor source with a gas flow rate of 0.1 mL/min was introduced. The carbon-deposition precursor source (in volume fraction) was a mixture of 60% methane, 10% hydrogen and 30% argon. Carbon deposition was performed on the silicon-carbon microspheres described in step (2) at 600° C. for 20 h to obtain a highly dense silicon-carbon anode material. The morphology is shown in FIG. 1, indicating that the material exhibits high sphericity.

The tap density was tested using the national standard GB/T 24533-2019. After testing, the tap density of the silicon-carbon anode material obtained in Example 1 was as high as 0.95 g/cm³.

The electrochemical performance of the silicon-carbon anode material obtained in Example 1 was tested in accordance with the method in Appendix D of the national standard GB/T 38823-2020. The results showed that the first discharge capacity of the anode material could reach 1645 mAh/g.

### Example 2

This example provides a method for preparing a silicon-carbon anode material based on organosilicon-derived waste silicon powder, which includes the following steps.
(1) The organosilicon-derived waste silicon powder, containing 93 wt % elemental silicon, 6.2 wt % copper, and 0.8 wt % organosilicon residue, was subjected to a single rapid annealing treatment under an air atmosphere with an air flow rate of 10 mL/min. The temperature was raised to 1000° C. at a heating rate of 500° C./min and was maintained for 0.1 h. After annealing, the waste silicon powder was allowed to cool naturally to 20° C. together with the furnace, accompanied by air during cooling. The rapidly annealed waste silicon powder was then subjected to acid leaching in a hydrofluoric acid solution (the concentration of the hydrofluoric acid was 5 mol/L) with a liquid-to-solid ratio of 10 mL:1 g at 0° C. for 5 h under stirring. After acid leaching, the powder was filtered, washed, and dried to obtain modified waste silicon powder.
(2) The modified waste silicon powder obtained in step (1) was subjected to high-energy ball milling with mesophase carbon microspheres under the conditions of a rotation speed of 1200 r/min and a milling time of 10 h, where the mass of the mesophase carbon microspheres was 60 wt % of the mass of the modified waste silicon powder, whereby a modified waste silicon powder abrasive having an average particle size of 0.3 μm was obtained; the modified waste silicon powder abrasive, citric acid, and water were mixed, where the mass of the citric acid was 10 wt % of the mass of the modified waste silicon powder abrasive, whereby a precursor solution having a solid content of 5 wt % was obtained; argon gas was introduced, and the precursor solution was subjected to spray granulation at a feeding rate of 1 mL/min, a gas flow rate of 0.01 mL/min, and a temperature of 350° C., whereby highly spherical silicon-carbon microspheres having an average particle size of 10 μm were self-assembled.
(3) A carbon-deposition precursor source having a gas flow rate of 10 mL/min was introduced. The carbon-deposition precursor source (in volume fraction) was a mixture of 40% methane, 50% hydrogen and 10% argon. Carbon deposition was performed on the silicon-carbon microspheres obtained in step (2) at 800° C. for 1 h, whereby a highly dense silicon-carbon anode material was obtained. The morphology was as shown in FIG. 2, indicating that the material had good sphericity and a smooth and dense surface.

The tap density was tested by using the method of Example 1, and the test results showed that the tap density of the silicon-carbon anode material obtained in Example 2 reached as high as 0.93 g/cm³.

The electrochemical performance of the silicon-carbon anode material obtained in Example 2 was tested by using the electrochemical performance testing method of Example 1, and the results showed that the silicon-carbon anode material exhibited an initial discharge capacity of 2002 mAh/g when used as an anode material.

### Example 3

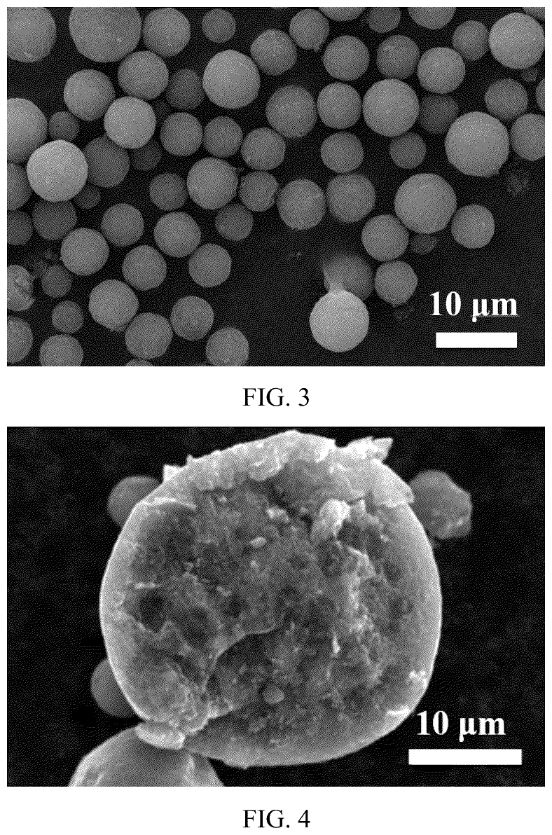

This example provides a method for preparing a silicon-carbon anode material based on organosilicon-derived waste silicon powder, which includes the following steps.
(1) The organosilicon-derived waste silicon powder contained 90.5 wt % elemental silicon, 8.4 wt % copper component, and 1.1 wt % organosilicon residue. The organosilicon-derived waste silicon powder was subjected to two rapid annealing treatments under a nitrogen atmosphere at a nitrogen flow rate of 600 mL/min, and the heating rate was 300° C./min to reach an annealing temperature of 1000° C., followed by a holding time of 0.5 h. After the annealing was completed, natural cooling to 20° C. was performed together with the furnace, during which nitrogen was maintained. The rapidly annealed waste silicon powder was then subjected to acid leaching in a nitric acid solution having a concentration of 3 mol/L, where the liquid-to-solid ratio of the nitric acid solution to the rapidly annealed waste silicon powder was 3 mL: 1 g, and the acid leaching was conducted at 80° C. under stirring for 1 h. After the acid leaching was completed, filtration, washing, and drying were performed, whereby modified waste silicon powder was obtained.
(2) The modified waste silicon powder obtained in step (1) was subjected to sand milling with graphite and carbon nanotubes under the conditions of a rotation speed of 1500 r/min and a milling time of 5 h, where the mass of the graphite was 60 wt % of the mass of the modified waste silicon powder, and the mass of the carbon nanotubes was 10 wt % of the mass of the modified waste silicon powder, whereby a modified waste silicon powder abrasive having an average particle size of 0.1 μm was obtained. The modified waste silicon powder abrasive, phenolic resin, MgCl₂, and ethanol were mixed, where the mass of the phenolic resin was 20 wt % of the mass of the modified waste silicon powder abrasive, and the mass of MgCl₂ was 1 wt % of the mass of the modified waste silicon powder abrasive, whereby a precursor solution having a solid content of 20 wt % was obtained. Argon was introduced, and the precursor solution was subjected to spray granulation at a feeding rate of 5 mL/min, a gas flow rate of 200 mL/min, and a temperature of 110° C., whereby highly spherical silicon-carbon microspheres having an average particle size of 8 μm were self-assembled.
(3) A carbon-deposition precursor source having a gas flow rate of 50 mL/min, which was a mixture of 50% carbon monoxide, 40% hydrogen, and 10% argon by volume, was introduced, and carbon deposition was performed on the silicon-carbon microspheres obtained in step (2) at 700° C. for 2 h, whereby a highly dense silicon-carbon anode material was obtained. The morphology was as shown in FIG. 3, indicating that the material exhibited high sphericity.

The tap density was tested by using the method of Example 1, and the test results showed that the tap density of the silicon-carbon anode material obtained in Example 3 reached as high as 0.89 g/cm³.

The electrochemical performance of the silicon-carbon anode material obtained in Example 3 was tested by using the electrochemical performance testing method of Example 1, and the results showed that the silicon-carbon anode material exhibited an initial discharge capacity of 1986 mAh/g when used as an anode material.

### Example 4

This example provides a method for preparing a silicon-carbon anode material based on organosilicon-derived waste silicon powder, which includes the following steps.
(1) The organosilicon-derived waste silicon powder, containing 88 wt % elemental silicon, 10.5 wt % copper component, and 1.5 wt % organosilicon residue, was subjected to one rapid annealing treatment under a nitrogen atmosphere, where the nitrogen gas flow rate was 300 mL/min, and the heating rate was 500° C./min to reach an annealing temperature of 1500° C., followed by a holding time of 0.2 h. After the annealing was completed, natural cooling to 20° C. was performed together with the furnace, during which nitrogen gas was maintained. The rapidly annealed waste silicon powder was then subjected to acid leaching in a hydrochloric acid-H₂O₂ mixed solution having a hydrochloric acid concentration of 2 mol/L and an H₂O₂ concentration of 10 mol/L, where the liquid-to-solid ratio of the mixed solution to the rapidly annealed waste silicon powder was 8 mL: 1 g, and the acid leaching was conducted at 60° C. under stirring for 5 h. After the acid leaching was completed, filtration, washing, and drying were performed, whereby modified waste silicon powder was obtained.
(2) The modified waste silicon powder obtained in step (1) was subjected to sand milling with pitch under the conditions of a rotation speed of 1300 r/min and a milling time of 10 h, where the mass of the pitch was 20 wt % of the mass of the modified waste silicon powder, whereby a modified waste silicon powder abrasive having an average particle size of 0.1 μm was obtained. The modified waste silicon powder abrasive, glucose, NaCl, and water were mixed, where the mass of the glucose was 60 wt % of the mass of the modified waste silicon powder abrasive, and the mass of NaCl was 6 wt % of the mass of the modified waste silicon powder abrasive, whereby a precursor solution having a solid content of 30 wt % was obtained. Argon gas was introduced, and the precursor solution was subjected to spray granulation at a feeding rate of 1 mL/min, a gas flow rate of 200 mL/min, and a temperature of 150° C., whereby highly spherical silicon-carbon microspheres having an average particle size of 25 μm were self-assembled.
(3) A carbon-deposition precursor source having a gas flow rate of 80 mL/min, which was a mixture of 10% methane, 40% hydrogen, and 50% argon by volume, was introduced, and carbon deposition was performed on the silicon-carbon microspheres obtained in step (2) at 1000° C. for 1 h, whereby a silicon-carbon anode material was obtained. The morphology was as shown in FIG. 4, indicating that the silicon-carbon composite material exhibited an internal porous structure and an external dense structure.

The tap density was tested by using the method of Example 1, and the test results showed that the tap density of the silicon-carbon anode material obtained in Example 4 reached as high as 1.10 g/cm³.

The electrochemical performance of the silicon-carbon anode material obtained in Example 4 was tested by using the electrochemical performance testing method of Example 1, and the results showed that the silicon-carbon anode material exhibited an initial discharge capacity of 2234 mAh/g when used as an anode material.

### Example 5

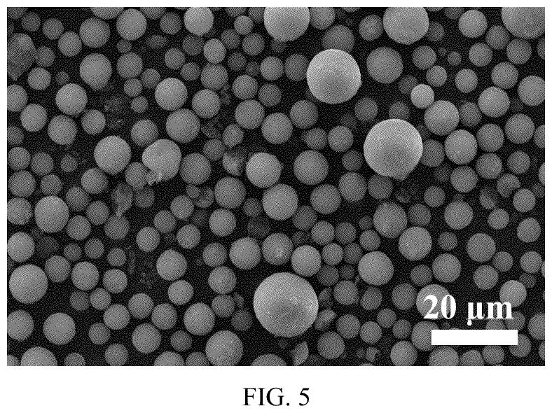

This example provides a method for preparing a silicon-carbon anode material based on organosilicon-derived waste silicon powder, which includes the following steps.
(1) The organosilicon-derived waste silicon powder, containing 89.4 wt % elemental silicon, 9.8 wt % copper component, and 0.6 wt % organosilicon residue, was subjected to one rapid annealing treatment under an argon atmosphere, where the argon gas flow rate was 400 mL/min, and the heating rate was 300° C./min to reach an annealing temperature of 600° C., followed by a holding time of 1 h. After the annealing was completed, natural cooling to 20° C. was performed together with the furnace, during which argon gas was maintained. The rapidly annealed waste silicon powder was then subjected to acid leaching in a hydrofluoric acid-hydrochloric acid mixed solution having a hydrofluoric acid concentration of 1 mol/L and a hydrochloric acid concentration of 1 mol/L, where the liquid-to-solid ratio of the mixed solution to the rapidly annealed waste silicon powder was 20 mL: 1 g, and the acid leaching was conducted at 20° C. under stirring for 2 h. After the acid leaching was completed, filtration, washing, and drying were performed, whereby modified waste silicon powder was obtained.
(2) The modified waste silicon powder obtained in step (1) was subjected to sand milling under the conditions of a rotation speed of 2000 r/min and a milling time of 20 h, whereby a modified waste silicon powder abrasive having an average particle size of 0.05 μm was obtained. The modified waste silicon powder abrasive, glucose, citric acid, CaCl₂), and ethylene glycol were mixed, where the mass of glucose was 40 wt % of the mass of the modified waste silicon powder abrasive, the mass of citric acid was 20 wt % of the mass of the modified waste silicon powder abrasive, and the mass of CaCl₂) was 4 wt % of the mass of the modified waste silicon powder abrasive, whereby a precursor solution having a solid content of 10 wt % was obtained. Argon gas was introduced, and the precursor solution was subjected to spray granulation at a feeding rate of 120 mL/min, a gas flow rate of 50 mL/min, and a temperature of 80° C., whereby highly spherical silicon-carbon microspheres having an average particle size of approximately 15 μm were self-assembled.
(3) A carbon-deposition precursor source having a gas flow rate of 10 mL/min, which was a mixture of 30% acetylene, 30% hydrogen, and 40% argon by volume, was introduced, and carbon deposition was performed on the silicon-carbon microspheres obtained in step (2) at 1100° C. for 1 h, whereby a highly dense silicon-carbon anode material was obtained. The morphology was as shown in FIG. 5, indicating that the material exhibited high sphericity and a uniform distribution.

The tap density was tested by using the method of Example 1, and the test results showed that the tap density of the silicon-carbon anode material obtained in Example 5 reached as high as 0.88 g/cm³.

The electrochemical performance of the silicon-carbon anode material obtained in Example 5 was tested by using the electrochemical performance testing method of Example 1, and the results showed that the silicon-carbon anode material exhibited an initial discharge capacity of 2018 mAh/g when used as an anode material.

The above descriptions are only preferred examples of the present invention. It should be noted that those of ordinary skill in the art can also make several improvements and modifications without departing from the principle of the present invention, and such improvements and modifications shall fall within the protection scope of the present invention.

What is claimed is:

1. A method for preparing a silicon-carbon anode material based on organosilicon-derived waste silicon powder, comprising the following steps:
(1) performing rapid annealing treatment on the organosilicon-derived waste silicon powder to obtain rapidly annealed waste silicon powder, and mixing the rapidly annealed waste silicon powder with an acid solution for acid leaching to obtain modified waste silicon powder;
(2) performing mechanical grinding on the modified waste silicon powder in the step (1) to obtain a modified waste silicon powder abrasive, mixing the modified waste silicon powder abrasive with an organic carbon source and a solvent to obtain a precursor solution, and performing spray granulation on the precursor solution to obtain silicon-carbon microspheres; and
(3) introducing a carbon-deposition precursor source, and performing carbon deposition on the silicon-carbon microspheres in the step (2) to obtain the silicon-carbon anode material; wherein
in the step (1), the organosilicon-derived waste silicon powder contains elemental silicon, copper component, and organosilicon residue; and a content of the elemental silicon is 60-95 wt %, a content of the copper component is 0.1-15 wt %, and a content of the organosilicon residue is 0.1-20 wt %;
in the step (1), a temperature for the rapid annealing treatment is 200-1500° C., a holding time for the rapid annealing treatment is 0.1 h-20 h, and the rapid annealing treatment is performed 1-5 times;
in the step (1), the acid solution comprises an oxidizing agent, the oxidizing agent is H₂O₂, Fe(NO₃)₃, KMnO₄, KBrO₃, K₂Cr₂O₇, or Na₂S₂O₈, and a concentration of the oxidizing agent in the acid solution is 0-10 mol/L; and
in the step (3), the carbon-deposition precursor source is a mixture of an active gas, hydrogen, and argon; the active gas is methane, acetylene, or carbon monoxide; and a volume fraction of the active gas in the carbon-deposition precursor source is 10-60%, a volume fraction of the hydrogen in the carbon-deposition precursor source is 10-50%, and a volume fraction of the argon in the carbon-deposition precursor source is 10-50%.

2. The method for preparing the silicon-carbon anode material based on the organosilicon-derived waste silicon powder according to claim 1, wherein in the step (1), an atmosphere for the rapid annealing treatment is air, argon, or nitrogen, a gas flow rate during the rapid annealing treatment is 10-600 mL/min, and a heating rate to the temperature for the rapid annealing treatment is 20-500° C./min.

3. The method for preparing the silicon-carbon anode material based on the organosilicon-derived waste silicon powder according to claim 1, wherein in the step (1), acid in the acid solution is one or more selected from hydrochloric acid, sulfuric acid, nitric acid, and hydrofluoric acid, a concentration of the acid in the acid solution is 0.01-5 mol/L, a liquid-to-solid ratio of the acid solution to the rapidly annealed waste silicon powder is ≥3 mL: 1 g, a temperature for the acid leaching is 0-80° C., and a duration of the acid leaching is 0.01-20 h.

4. The method for preparing the silicon-carbon anode material based on the organosilicon-derived waste silicon powder according to claim 1, wherein in the step (2), the modified waste silicon powder is mixed with a carbon material and then subjected to the mechanical grinding, the carbon material is one or more of carbon fiber, mesophase carbon microspheres, graphite, hard carbon, porous activated carbon, carbon nanotubes, graphene, and pitch, and a mass of the carbon material is 0-100 wt % of a mass of the modified waste silicon powder.

5. The method for preparing the silicon-carbon anode material based on the organosilicon-derived waste silicon powder according to claim 1, wherein in the step (2), the organic carbon source comprises one or more of glucose, phenol-formaldehyde resin, polydopamine, and citric acid, a mass of the organic carbon source is 1-60 wt % of a mass of the modified waste silicon powder abrasive, a solid content of the precursor solution is 1-30 wt %, and an atmosphere used for the spray granulation is air, argon, or nitrogen; and a feed rate for the spray granulation is 1-120 mL/min, an inlet gas flow rate for the spray granulation is 0.01-200 mL/min, and a temperature for the spray granulation is 80-350° C.

6. The method for preparing the silicon-carbon anode material based on the organosilicon-derived waste silicon powder according to claim 5, wherein in the step (2), the precursor solution comprises a pore-forming agent, the pore-forming agent comprises one or more of NaCl, MgCl₂, LiCl, KCl, and CaCl₂), and a mass of the pore-forming agent is 0-6 wt % of the mass of the modified waste silicon powder abrasive.

7. The method for preparing the silicon-carbon anode material based on the organosilicon-derived waste silicon powder according to claim 1, wherein in the step (3), a gas flow rate of the carbon-deposition precursor source is 0.1-100 mL/min, a temperature for the carbon deposition is 400-1300° C., and a duration of the carbon deposition is 0.1-20 h.

8. A silicon-carbon anode material prepared by the method for preparing the silicon-carbon anode material based on the organosilicon-derived waste silicon powder according to claim 1.

9. The silicon-carbon anode material according to claim 8, wherein the silicon-carbon anode material is used in lithium-ion batteries.

10. The method for preparing the silicon-carbon anode material based on the organosilicon-derived waste silicon powder according to claim 2, wherein in the step (1), acid in the acid solution is one or more selected from hydrochloric acid, sulfuric acid, nitric acid, and hydrofluoric acid, a concentration of the acid in the acid solution is 0.01-5 mol/L, a liquid-to-solid ratio of the acid solution to the rapidly annealed waste silicon powder is ≥3 mL: 1 g, a temperature for the acid leaching is 0-80° C., and a duration of the acid leaching is 0.01-20 h.

11. The method for preparing the silicon-carbon anode material based on the organosilicon-derived waste silicon powder according to claim 4, wherein in the step (2), the organic carbon source comprises one or more of glucose, phenol-formaldehyde resin, polydopamine, and citric acid, a mass of the organic carbon source is 1-60 wt % of a mass of the modified waste silicon powder abrasive, a solid content of the precursor solution is 1-30 wt %, and an atmosphere used for the spray granulation is air, argon, or nitrogen; and a feed rate for the spray granulation is 1-120 mL/min, an inlet gas flow rate for the spray granulation is 0.01-200 mL/min, and a temperature for the spray granulation is 80-350° C.

12. The method for preparing the silicon-carbon anode material based on the organosilicon-derived waste silicon powder according to claim 11, wherein in the step (2), the precursor solution comprises a pore-forming agent, the pore-forming agent comprises one or more of NaCl, MgCl₂, LiCl, KCl, and CaCl₂), and a mass of the pore-forming agent is 0-6 wt % of the mass of the modified waste silicon powder abrasive.

13. The silicon-carbon anode material according to claim 8, wherein in the step (1) of the method, an atmosphere for the rapid annealing treatment is air, argon, or nitrogen, a gas flow rate during the rapid annealing treatment is 10-600 mL/min, and a heating rate to the temperature for the rapid annealing treatment is 20-500° C./min.

14. The silicon-carbon anode material according to claim 8, wherein in the step (1) of the method, acid in the acid solution is one or more selected from hydrochloric acid, sulfuric acid, nitric acid, and hydrofluoric acid, a concentration of the acid in the acid solution is 0.01-5 mol/L, a liquid-to-solid ratio of the acid solution to the rapidly annealed waste silicon powder is ≥3 mL:1 g, a temperature for the acid leaching is 0-80° C., and a duration of the acid leaching is 0.01-20 h.

15. The silicon-carbon anode material according to claim 8, wherein in the step (2) of the method, the modified waste silicon powder is mixed with a carbon material and then subjected to the mechanical grinding, the carbon material is one or more of carbon fiber, mesophase carbon microspheres, graphite, hard carbon, porous activated carbon, carbon nanotubes, graphene, and pitch, and a mass of the carbon material is 0-100 wt % of a mass of the modified waste silicon powder.

16. The silicon-carbon anode material according to claim 8, wherein in the step (2) of the method, the organic carbon source comprises one or more of glucose, phenol-formaldehyde resin, polydopamine, and citric acid, a mass of the organic carbon source is 1-60 wt % of a mass of the modified waste silicon powder abrasive, a solid content of the precursor solution is 1-30 wt %, and an atmosphere used for the spray granulation is air, argon, or nitrogen; and a feed rate for the spray granulation is 1-120 mL/min, an inlet gas flow rate for the spray granulation is 0.01-200 mL/min, and a temperature for the spray granulation is 80-350° C.

17. The silicon-carbon anode material according to claim 16, wherein in the step (2) of the method, the precursor solution comprises a pore-forming agent, the pore-forming agent comprises one or more of NaCl, MgCl₂, LiCl, KCl, and CaCl₂), and a mass of the pore-forming agent is 0-6 wt % of the mass of the modified waste silicon powder abrasive.

18. The silicon-carbon anode material according to claim 8, wherein in the step (3) of the method, a gas flow rate of the carbon-deposition precursor source is 0.1-100 mL/min, a temperature for the carbon deposition is 400-1300° C., and a duration of the carbon deposition is 0.1-20 h.

19. The silicon-carbon anode material according to claim 13, wherein the silicon-carbon anode material is used in lithium-ion batteries.

20. The silicon-carbon anode material according to claim 14, wherein the silicon-carbon anode material is used in lithium-ion batteries.
